(19) United States
(12) Patent Application Publication
(10) Pub. No.: US 2010/0326706 A1
(43) Pub. Date: Dec. 30, 2010

(54) ELECTRONIC APPARATUS AND FLEXIBLE PRINTED WIRING BOARD

(76) Inventors: Kiyomi Muro, Hachioji-shi (JP); Sadahiro Tamai, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/797,285

(22) Filed: Jun. 9, 2010

(30) Foreign Application Priority Data
Jun. 30, 2009 (JP) 2009-156269

(51) Int. Cl. H05K 1/00

(52) U.S. Cl. 174/254

(57) ABSTRACT

According to one embodiment, an electronic apparatus includes a flexible printed wiring board. The printed wiring board includes a conductive layer including a signal line and a ground line, a second insulating layer layered on the conductive layer and including openings open to above the ground line, a ground layer covering the signal line and electrically connected to the ground line, and a third insulating layer covering the ground layer. The ground layer includes first and second conductive pastes. The first conductive paste is filled in the openings so as to cover the ground line exposed to bottoms of the openings. The second conductive paste is applied so as to continuously cover the first conductive paste and the second insulating layer. The second conductive paste has a smaller volume resistivity than the first conductive paste.

### CROSS-REFERENCE TO RELATED APPLICATIONS

This application is based upon and claims the benefit of priority from Japanese Patent Application No. 2009-156269, filed Jun. 30, 2009; the entire contents of which are incorporated herein by reference.

### FIELD

Embodiments described herein relate generally to an electronic apparatus such as a portable computer mounting a flexible printed wiring board capable of coping with increased transfer rate and a flexible printed wiring board including a ground layer made of a conductive paste.

### BACKGROUND

Flexible printed wiring boards which can be freely bent are widely used as wiring components in electronic apparatuses, such as portable computers. Recent electronic apparatuses comply with high-speed transfer standards such as Serial Advanced Technology Attachment (S-ATA) in accordance with increased data transfer rate and data transfer capacity. There is thus a tendency wherein high-speed transfer capability not required at present is demanded for flexible printed wiring boards for electronic apparatuses.

Jpn. Pat. Appln. Publication No. 8-125380 discloses a double-sided flexible printed wiring board which can support high-speed transfer. A double-sided flexible printed wiring board of this type comprises: a first shielding layer; a conductive layer on the first shielding layer and comprising a signal line and a ground line; and a second shielding layer on the conductive layer.

The first and second shielding layers are made of a conductive adhesive agent and a metal foil, and sandwich the conductive layer. The conductive adhesive agent intervenes between the metal foil and the ground line, and electrically connects the metal foil and the ground line.

According to a conventional double-sided flexible printed wiring board, a metal foil is layered on each of two surfaces of the conductive layer. Therefore, a thickness dimension of the double-sided flexible printed wiring board inevitably increases. As a result, the double-sided flexible printed wiring board is heavy, and flexibility is impaired. Accordingly, workability is impaired when the double-sided flexible printed wiring board is wired in a narrows space in an electronic apparatus.

On the other hand, in a single-sided flexible printed wiring board based on a single-sided copper-clad laminate, a conductive layer comprising a signal line and a ground line is covered with an insulating layer. Further, a conductive paste is coated on the insulating layer. The insulating layer includes plural openings which are open to above the ground line. The conductive paste is filled in the openings of the insulating layer, and is electrically connected to the ground line.

In the single-sided flexible printed wiring board as described above, the conductive paste functions as a ground layer which covers the signal line. Therefore, the number of metal foils which may cause disadvantages relating to mass can be reduced. Accordingly, the single-sided flexible printed wiring board can be lighter and thinner, compared with the double-sided flexible printed wiring board, and achieves easy handling.

The conductive paste used for the single-sided flexible printed wiring board has a volume resistivity of about 100 to 50 μΩ·cm. There is no denying that a signal transfer loss occurs at transfer ends of high-frequency signals due to resistance inherent to the conductive paste.

For example, a single-sided flexible printed wiring board comprising a transfer path according to a differential transfer method enables proper data transfer without loss at a differential data transfer rate according to present standards, such as S-ATA1 (transfer rate 1.5 Gbits/s).

However, transfer loss begins to have a great influence in S-ATA2 (transfer rate 3.0 Gbits/s) which can be supported by the double-sided flexible printed wiring board disclosed in the aforementioned publication. Consequently, further increase in data transfer rate cannot be supported.

In order to cope with this problem, the present inventor attempted to use a conductive paste having a small volume resistivity of 30 μΩ·cm or less, for example, in place of a conventional conductive paste. By using a conductive paste having a small volume resistivity, resistance of the conductive paste which causes transfer loss can be reduced to be small.

Meanwhile, the conductive paste having a small volume resistivity has a great thixotropic ratio and maintains a highly viscous state. Therefore, for example, when coating the conductive paste over an insulating layer by a screen printing method, the conductive paste is difficult to fill compactly in openings in the insulating layer.

In other words, air is easily taken in when a highly viscous conductive paste is filled in openings. The air taken in forms voids which remain in the conductive paste filled in the openings.

As a result, careful attention needs be paid so that voids are not produced when coating the conductive paste over an insulating layer. Accordingly, workability deteriorates extremely when manufacturing a flexible printed wiring board.

### BRIEF DESCRIPTION OF THE DRAWINGS

FIG. 1 is a perspective view of an exemplary portable computer according to a first embodiment;

FIG. 2 is an exemplary perspective view illustrating a positional relationship between a printed circuit board, a hard disk drive device, and a flexible printed wiring board, which are contained in the housing, in the first embodiment;

FIG. 3 is an exemplary perspective view illustrating the flexible printed wiring board contained in the housing, in the first embodiment;

FIG. 4 is an exemplary plan view of the flexible printed wiring board according to the first embodiment;

FIG. 5 is an exemplary cross-sectional view cut along a line F5-F5 in FIG. 4;

FIG. 6 is an exemplary cross-sectional view of a single-sided copper-clad laminate used in the first embodiment;

FIG. 7 is an exemplary cross-sectional view illustrating a state in which a conductive layer comprising a signal line and a ground line is formed on the single-sided copper-clad laminate, in the first embodiment;

FIG. 8 is an exemplary cross-sectional view of a laminated structure in which openings are formed, in the first embodiment;

FIG. 9 is an exemplary cross-sectional view illustrating a state in which a laminated structure is layered on a single-sided copper-clad laminate where a conductive layer is formed, in the first embodiment;

FIG. 10 is an exemplary cross-sectional view illustrating a state in which a first conductive paste is filled in the openings in a second insulating layer, in the first embodiment;

FIG. 11 is an exemplary cross-sectional view illustrating a state in which the second conductive paste is applied onto a surface of the second insulating layer and the first conductive paste, in the first embodiment; and

FIG. 12 is an exemplary cross-sectional view of a flexible printed wiring board according to a second embodiment.

### DETAILED DESCRIPTION

In general, according to one embodiment, an electronic apparatus includes a housing and a flexible printed wiring board provided in the housing. The flexible printed wiring board comprises first to third insulating layers, a conductive layer, and a ground layer. The conductive layer comprises a signal line and a ground line, and is layered on the first insulating layer. The second insulating layer is layered on the conductive layer, and comprises plural openings open to above the ground line. The ground layer is layered on the second insulating layer so as to cover the signal line, and is electrically connected to the ground line. The third insulating layer covers the ground layer.

The ground layer is constituted by a first conductive paste and a second conductive paste. The first conductive paste is filled in the openings so as to cover the ground line exposed from the bottoms of the openings. The second conductive paste is coated so as to continuously cover the first conductive paste and the second insulating layer. The second conductive paste has a smaller volume resistivity than the first conductive paste.

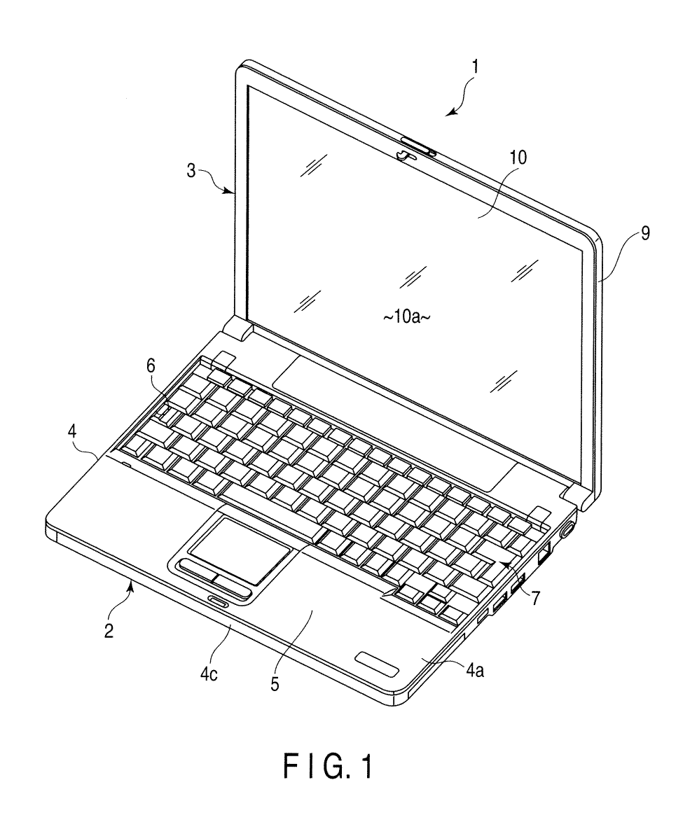

Hereinafter, the first embodiment will be described, referring to FIGS. 1 to 11.

FIG. 1 discloses a portable computer 1 as an example of an electronic apparatus. The portable computer 1 comprises a computer main body 2 and a display module 3.

The computer main body 2 comprises a first housing 4 made of synthetic resin. The first housing 4 has a shape like a flat box having an upper wall 4a, a bottom wall 4b, and a peripheral wall 4c. A palm rest 5 and a keyboard mounting part 6 are formed on the upper wall 4a of the first housing 4. The keyboard mounting part 6 supports a keyboard 7.

The display module 3 comprises a second housing 9. The second housing 9 has a shape like a flat box whose size is substantially the same as the first housing 4, and contains a liquid crystal display panel 10. The liquid crystal display panel 10 comprises a screen 10a which displays text information and image information. The screen 10a is exposed to the outside of the display module 3 from a front surface of the second housing 9.

The display module 3 is supported at a rear end part of the computer main body 2 by a hinge device (not shown). The display module 3 is pivotable between a closed position and an opened position. At the closed position, the display module 3 lies over the computer main body 2 so as to cover the palm rest 5 and keyboard 7 from upside. At the opened position, the display module 3 stands up from the rear end part of the computer main body 2 so as to expose the palm rest 5, keyboard 7, and screen 10a.

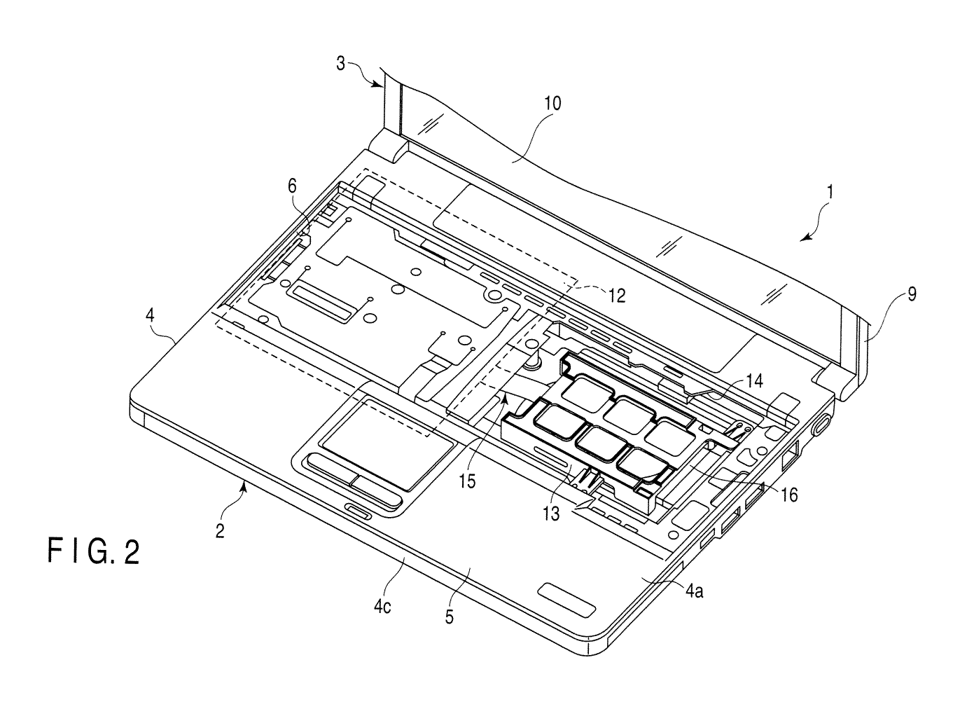

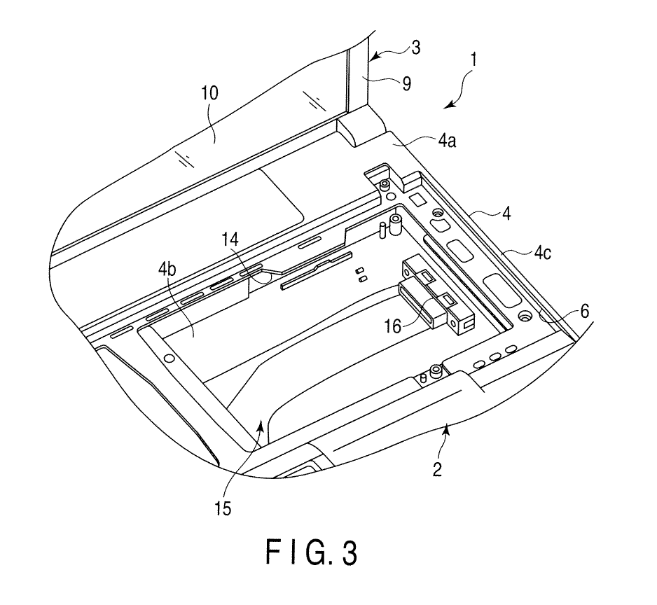

As illustrated in FIGS. 2 and 3, the first housing 4 of the computer main body 2 contains, for example, major components such as a printed circuit board 12 as a mother board, and a hard disk drive device 13.

The printed circuit board 12 and hard disk drive device 13 are arranged laterally within the first housing 4 below the keyboard 7. The hard disk drive device 13 is contained in the first housing 4 to be detachable through a disk insertion port 14 formed in the keyboard mounting part 6.

A flexible printed wiring board 15 is provided inside the first housing 4. The flexible printed wiring board 15 electrically connects the printed circuit board 12 and the hard disk drive device 13 to each other. The flexible printed wiring board 15 is of a band type which has a connector 16 at one end, and is wired through a gap between the bottom wall 4b of the first housing 4 and the hard disk drive device 13. The connector 16 positioned at an end of the flexible printed wiring board 15 is detachably connected to the hard disk drive device 13.

As illustrated in FIG. 5, the flexible printed wiring board 15 comprises a first insulating layer 18, a conductive layer 19, a second insulating layer 20, a ground layer 21, and a third insulating layer 22.

The first insulating layer 18 is a part to become a base of the flexible printed wiring board 15 and is made of, for example, a polyimide film.

The conductive layer 19 is layered on the first insulating layer 18 through an adhesive agent 23. The conductive layer 19 comprises a signal line 24 and a ground line 25. The signal line 24 comprises a pair of differential transfer lines 24a and 24b. The differential transfer lines 24a and 24b are provided in parallel with each other at an constant interval maintained in between. The ground line 25 is provided in parallel with the differential transfer line 24a. The differential transfer lines 24a and 24b and ground line 25 extend along a length direction of the flexible printed wiring board 15. Tip ends of the differential transfer lines 24a and 24b and ground line 25 are electrically connected to the connector 16.

The second insulating layer 20 is layered on the conductive layer 19 with an adhesive agent 26 inserted below. The second insulating layer 20 is made of, for example, a polyimide film. The second insulating layer 20 in cooperation with the adhesive agent 26 covers the conductive layer 19.

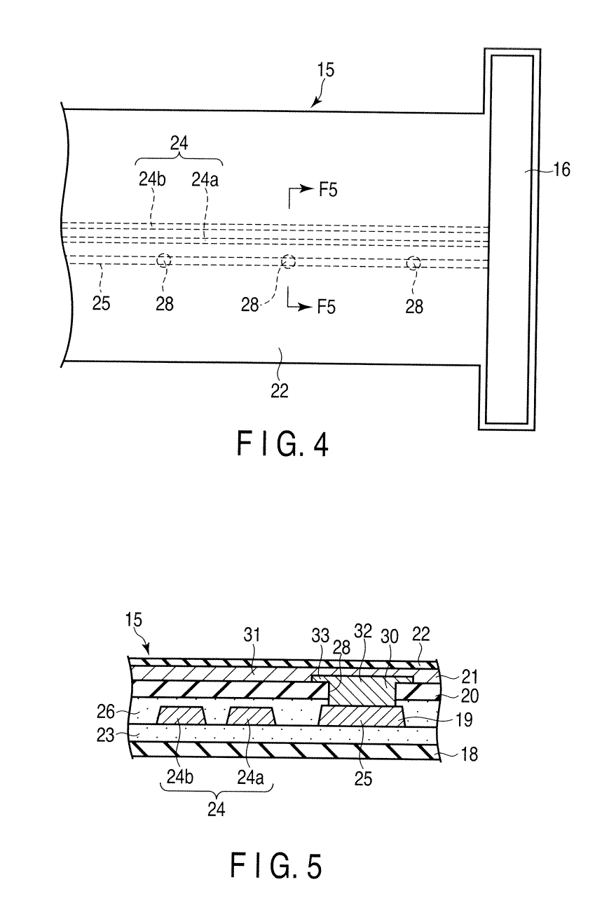

As illustrated in FIGS. 4 and 5, the second insulating layer 20 is provided with plural circular openings 28 at positions corresponding to the ground line 25. The openings 28 are arranged at intervals along the ground line 25. The openings 28 each are open to above the ground line 25, penetrating the second insulating layer 20 and adhesive agent 26. Therefore, the ground line 25 is exposed to the bottoms of the openings 28.

A ground layer 21 is layered on the second insulating layer 20. The ground layer 21 is formed by applying a first conductive paste 30 and a second conductive paste 31 to the second insulating layer 20. The first and second conductive pastes 30 and 31 each are a mixture of conductive particles such as silver particles with binder resin which binds the conductive particles. For example, a silver paste or a mixed paste of silver and carbon may be used. A means for applying the first and second conductive pastes 30 and 31 is, for example, a screen printing method.

The first conductive paste 30 is compactly filled in the openings 28 and covers the ground line 25 exposed to the bottoms of the openings 28. According to this embodiment, the first conductive paste 30 includes conducting parts 32 swelling beyond the second insulating layer 20. A flange part 33 is provided on outer periphery of each of the conducting parts 32. The flange parts 33 each overlap the second insulating layer 20 and have a greater diameter than the openings 28.

As illustrated in FIG. 5, the first conductive paste 30 filled in the openings 28 is positioned out of a part of the second insulating layer 20 which covers the differential transfer lines 24a and 24b. Therefore, a paste which has a volume resistivity of, for example, 140 μΩ·cm is used as the first conductive paste 30. The first conductive paste 30 having a high volume resistivity has a small thixotropic ratio, and maintains a state of low viscosity at the time point when the first conductive paste 30 is filled in the openings 28.

The second conductive paste 31 continuously covers a surface of the second insulating layer 20 and the conducting parts 32 of the first conductive paste 31. The second conductive paste 31 serves as a ground layer by covering the differential transfer lines 24a and 24b from above the second insulating layer 20. Therefore, a paste which has a volume resistivity of, for example, 30 μΩ·cm or less is used as the second conductive paste 31.

In other words, the second conductive paste 31 has a smaller volume resistivity than the first conductive paste 30. The second conductive paste 31 having a small volume resistivity has a great thixotropic ratio, and maintains a state of high viscosity at the time point when the paste 31 is applied to the second insulating layer 20. In order to reduce the volume resistivity of the second conductive paste 31, for example, the ratio of the conductive particles may be increased or the shape of the conductive particles may be enlarged to be larger than that of the conductive particles of the first conductive paste 30. The shape of the conductive particles can be enlarged by forming the conductive particles to be flakey.

Accordingly, the ground layer 21 according to this embodiment has different volume resistivities respectively at a part corresponding to the openings 28 and at a part outside the openings

The third insulating layer 22 is layered on the ground layer 21, and entirely covers the ground layer 21. The ground layer 21 is protected by the third insulating layer 22.

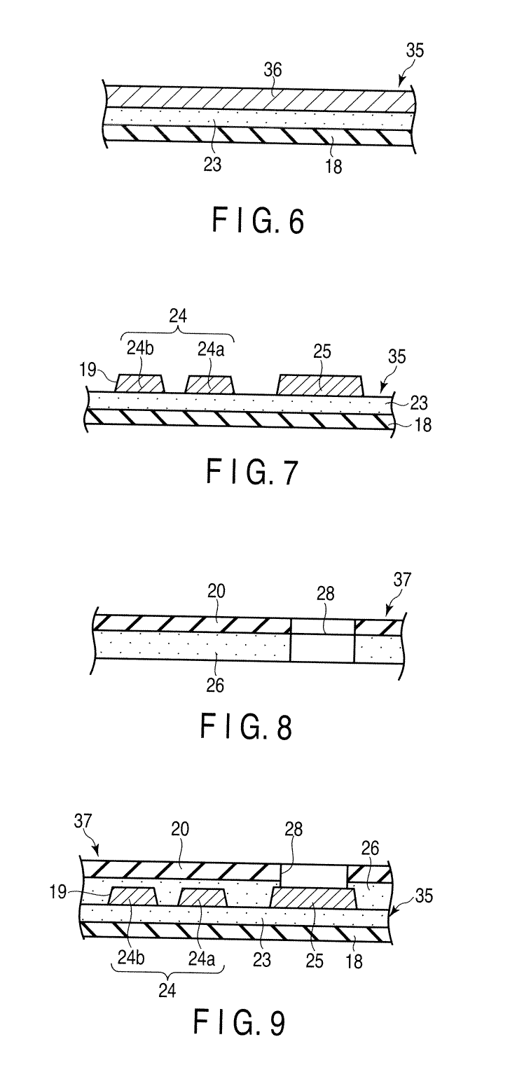

Next, a procedure of manufacturing the flexible printed wiring board 15 will be described additionally referring to FIGS. 6 to 11.

At first, a single-sided copper-clad laminate 35 which forms a base for the flexible printed wiring board 15 is prepared. As illustrated in FIG. 6, the single-sided copper-clad laminate 35 has a three-layer structure comprising a first insulating layer 18 using a polyimide film, and a copper foil 36 which is layered over the first insulating layer 18 with an adhesive agent 23 inserted therebetween.

Thereafter, as illustrated in FIG. 7, an etching processing is performed on the copper foil 36 of the single-sided copper-clad laminate 35, thereby to form a conductive layer 19 including a signal line 24 and a ground line 25.

Subsequently, a laminated structure 37 as illustrated in FIG. 8 is prepared. The laminated structure 37 has a two-layer structure comprising a second insulating layer 20 using a polyimide film, and an adhesive agent 26 applied to the entire back surface of the second insulating layer 20.

Thereafter, plural openings 28 are formed, for example, by performing a laser process or a drill process on the laminated structure 37. The openings 28 are arranged at an interval maintained between each other so as to correspond to the position of the ground line 25.

After forming the openings 28 in the laminated structure 37, the laminated structure 37 is heated/pressed with this laminated structure 37 overlapped on the single-sided copper-clad laminate 35 where the conductive layer 19 is formed. In this manner, as illustrated in FIG. 9, the single-sided copper-clad laminate 35 and the laminated structure 37 form an integral structure, and the conductive layer 19 is covered with the second insulating layer 20 and adhesive agent 26. Accordingly, the openings 28 are aligned with the ground line 25, which is partially exposed to the outside of the second insulating layer 20 from the openings 28.

Thereafter, as illustrated in FIG. 10, the first conductive paste 30 is filled in the openings 28 of the second insulating layer 20. In this embodiment, the first conductive paste 30 of a predetermined amount is filled in the openings 28 by the screen printing method in a manner that the first conductive paste 30 swells out of the second insulating layer 20. As a result, conducting parts 32 each having a flange part 33 are formed above the openings 28. Accordingly, the ground line 25 exposed to the bottoms of the openings 28 is covered with the first conductive paste 30.

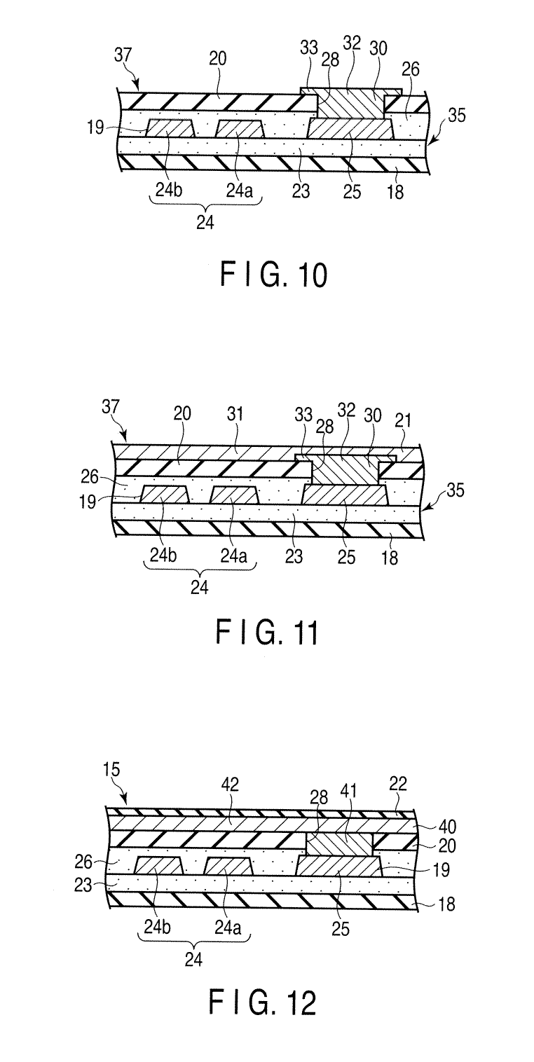

After completion of printing of the first conductive paste 30, the first conductive paste 30 is dried. Subsequently, as illustrated in FIG. 11, the second conductive paste 31 is applied onto the second insulating layer 20. In this embodiment, the second conductive paste 31 of a predetermined amount is applied onto the second conductive paste 20 by the screen printing method, so as to continuously cover the conducting parts 32 of the first conductive paste 30.

After completion of printing of the second conductive paste 31, the second conductive paste 31 is dried. As a result, the first and second conductive pastes 30 and 31 are hardened thereby to form the ground layer 21. Further, the ground layer 21 and the ground line 25 are electrically connected to each other through the first conductive paste 30 filled in the openings 28.

Finally, a surface and ends of the ground layer 21 are covered with a third insulating layer 22. Through the process as described above, a series of processing steps of manufacturing the flexible printed wiring board 15 are completed.

According to the first embodiment, a portion of the ground layer 21 which covers the signal line 24 including the differential transfer lines 24a and 24b is formed of the second conductive paste 31, and portions of the ground layer 21 which are filled in the openings 28 are formed of the first conductive paste 30. The second conductive paste 31 has a volume resistivity of, for example, 30 μΩ·cm or less, which is far smaller that of the first conductive paste 30.

Therefore, the second conductive paste 31 forms a ground line having low electrical resistance throughout the whole length of the differential transfer lines 24a and 24b, and forms a ground line 21 which causes less transfer loss.

As a result, for example, signal transfer according to a high-speed transfer standard such as S-ATA2 (transfer rate 3.0 Gbits/s), S-ATA3 (transfer rate 6.0 Gbits/s), or an even higher speed standard can be supported naturally. Therefore, data transfer with stable operation is possible.

Further, the volume resistivity of the first conductive paste 30 filled in the openings 28 is 140 μΩ·cm which is substantially equal to a volume resistivity of a common conductive paste used conventionally. This type of conductive paste has a small thixotropic ratio, and maintains a state of low viscosity at the time point when the conductive paste is applied to the second insulating layer 20.

Therefore, the first conductive paste 30 attains such excellent fluidity that the first conductive paste 30 can be compactly filled in the openings 28. Accordingly, air is barely taken in when filling the first conductive paste 30. As a result, voids can be prevented in the first conductive paste 30 filled in the openings 28.

Therefore, workability in applying the first conductive paste 30 can be improved, and the flexible printed wiring board 15 can accordingly be easily manufactured.

Since the second conductive paste 31 contains silver particles at a higher content than the first conductive paste 30, costs for the second conductive paste 31 are inevitably high. Therefore, according to the first embodiment, the openings 28 in the second insulating layer 20 which are positioned out of the differential transfer lines 24a and 24b are filled with the first conductive paste 30 whose volume resistivity is not much different from that of a conventional conductive paste. In other words, two types of conductive pastes 30 and 31 are used respectively for different purposes, so that the amount of the expensive second conductive paste 31 used is minimized. Therefore, manufacturing costs for the flexible printed wiring board 15 can be reduced.

According to the first embodiment, conducting parts which overhang the second insulating layer are formed as parts of the first conductive paste. However, the conducting parts are not mandatory components. For example, the surface of the first conductive paste and the surface of the second insulating layer may be positioned on one single plane.

Further, signal lines are not limited to differential transfer lines but may be, for example, signal lines each of which comprises a transfer line of a single end type.

FIG. 12 discloses a flexible printed wiring board 15 according to the second embodiment. In the second embodiment, a ground layer 40 has a different configuration from that of the first embodiment. The other parts of the configuration are the same as those of the first embodiment. Therefore, the same parts of the configuration of the second embodiment as those of the first embodiment will be denoted at the same reference symbols, and descriptions thereof will be omitted herefrom.

As illustrated in FIG. 12, the ground layer 40 comprises a plated layer 41 and a conductive paste 42. The plated layer 41 is compactly filled in openings 28 in a second insulating layer 20, and covers a ground line 25 exposed to the bottoms of the openings 28. In this embodiment, the plated layer 41 does not swell from the surface of the second insulating layer 20 but a surface of the plated layer 41 is positioned in the same plane as the surface of the second insulating layer 20.

The conductive paste 42 continuously covers surfaces of the second insulating layer 20 and plated layer 41 by a screen printing method. The conductive paste 42 serves as a ground layer by covering the differential transfer lines 24a and 24b from above the second insulating layer 20. A paste which has a volume resistivity of, for example, 30 μΩ·cm or less is used as the conductive paste 42 in this embodiment. The conductive paste 42 having the smaller volume resistivity has a greater thixotropic ratio, and maintains a state of high viscosity at the time point when applied to the second insulating layer 20. The conductive paste 42 is electrically connected to the ground line 25 through the plated layer 41 filled in the openings 28.

According to the second embodiment, a portion of the ground layer 40 which covers a signal line 24 including the differential transfer lines 24a and 24b is formed of the conductive paste 42, and portions of the ground layer 40 which are filled in the openings 28 are formed of the plated layer 41. The conductive paste 42 has a volume resistivity of, for example, 30 μΩ·cm or less, which is far smaller than a volume resistivity of a conventional conductive paste.

Therefore, the conductive paste 42 forms a ground line having low electrical resistance throughout the whole length of the differential transfer lines 24a and 24b, and accordingly forms the ground line 40 which causes less transfer loss.

Accordingly, as in the first embodiment, for example, signal transfer according to a high-speed transfer standard such as S-ATA2 (transfer rate 3.0 Gbits/s), S-ATA3 (transfer rate 6.0 Gbits/s), or an even higher speed standard can be supported naturally. Therefore, data transfer with stable operation is possible.

Further, the plated layer 41 is filled in the openings 28, and air is therefore not taken in when filling the first conductive paste 30. As a result, voids which are a problem for conductive pastes can be prevented. Hence, workability in manufacturing the flexible printed wiring board 15 can be improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising a housing and a flexible printed wiring board provided in the housing, the flexible printed wiring board comprising:
a first insulating layer;
a conductive layer layered on the first insulating layer, and comprising a signal line and a ground line;
a second insulating layer layered on the conductive layer, and comprising a plurality of openings open to above the ground line;
a ground layer layered on the second insulating layer so as to cover the signal line, and electrically connected to the ground line; and
a third insulating layer covering the ground layer, wherein
the ground layer comprises a first conductive paste filled in the plurality of openings so as to cover the ground line exposed to bottoms of the plurality of openings, and a second conductive paste applied so as to continuously cover the first conductive paste and the second insulating layer, the second conductive paste having a smaller volume resistivity than the first conductive paste.

2. The electronic apparatus of claim 1, wherein the second conductive paste has a greater thixotropic ratio than the first conductive paste.

3. The electronic apparatus of claim 2, wherein the signal line comprises a pair of differential transfer lines that transfer data at a rate according to a serial ATA standard.

4. The electronic apparatus of claim 3, wherein the first and second conductive pastes each contain conductive particles and binder resin that binds the conductive particles, and the second conductive paste is filled at a greater fill volume than the first conductive paste.

5. The electronic apparatus of claim 4, wherein the conductive particles of the second conductive paste have a larger shape than the conductive particles of the first conductive paste.

6. The electronic apparatus of claim 4, wherein the first and second conductive pastes are applied onto the second insulating layer by a screen printing method.

7. A flexible printed wiring board comprising:
a first insulating layer;
a conductive layer layered on the first insulating layer, and comprising a signal line and a ground line;
a second insulating layer layered on the conductive layer, and comprising a plurality of openings open to above the ground line;
a ground layer layered on the second insulating layer so as to cover the signal line, and electrically connected to the ground line; and
a third insulating layer covering the ground layer, wherein
the ground layer comprises a first conductive paste filled in the plurality of openings so as to cover the ground line exposed to bottoms of the plurality of openings, and a second conductive paste applied so as to continuously cover the first conductive paste and the second insulating layer, the second conductive paste having a smaller volume resistivity than the first conductive paste.

8. The flexible printed wiring board of claim 7, wherein the signal line comprises a pair of differential transfer lines that transfer data at a rate according to a serial ATA standard.

9. The flexible printed wiring board of claim 8, wherein the plurality of openings are arranged at an interval maintained between each other, on the ground line.

10. The flexible printed wiring board of claim 9, wherein the first conductive paste has flange parts which overhang the second insulating layer and are covered with the second conductive paste.

11. A flexible printed wiring board comprising:
a first insulating layer;
a conductive layer layered on the first insulating layer, and comprising a signal line and a ground line;
a second insulating layer layered on the conductive layer, and comprising a plurality of openings open to above the ground line;
a plated layer filled in the plurality of openings and electrically connected to the ground line exposed to bottoms of the plurality of openings;
a ground layer formed of a conductive paste applied so as to continuously cover the second insulating layer and the plated layer, the ground layer covering the signal line and electrically connected to the ground line through the plated layer; and
a third insulating layer covering the ground layer.

12. The flexible printed wiring board of claim 11, wherein the conductive paste has a volume resistivity of 30 μΩ·cm or less.
